(19) United States
(12) Patent Application Publication
(10) Pub. No.: US 2004/0146643 A1
(43) Pub. Date: Jul. 29, 2004

(54) METHOD OF DETERMINING DEPOSITION TEMPERATURE

(76) Inventors: Shih-Liang Chou, Hsinchu (TW); Tsung-Chin Wu, Hsinchu (TW); Tsung-De Lin, Hsinchu (TW); Tian-Jue Hong, Hsinchu (TW); Kou-Yow Tseng, Hsinchu (TW); Wen-Cheng Lien, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/248,500

(22) Filed: Jan. 24, 2003

(51) Int. Cl. C23C 16/00

(52) U.S. Cl. 427/255.28; 427/8

(57) ABSTRACT

A method of determining the deposition temperature, especially inside the reaction chamber of a chemical vapor deposition station. The method includes placing a deposition substrate inside the reaction chamber, forming a layer of metal silicide over the deposition substrate, measuring the silicon/metal atomic ratio and finding the deposition temperature according to a pre-determined temperature versus silicon/metal atomic ratio relationship. The method permits immediate determination as well as real-time monitoring of deposition temperature inside the station.

### BACKGROUND OF INVENTION

1. Field of Invention

The present invention relates to a method of determining the deposition temperature inside the reaction chamber of a chemical vapor deposition station. More particularly, the present invention relates to a method of determining the deposition temperature inside the reaction chamber of a chemical vapor deposition station through a relationship between temperature and silicon/metal atomic ratio.

2. Description of Related Art

In recent years, chemical vapor deposition has become a major tool for fabricating thin films on a substrate in semiconductor production. Whatever the types of thin films demanded by semiconductor device, they can be fabricated by conducting chemical vapor deposition. Examples are many, including the fabrication of metallic layers such as a tungsten layer, a titanium layer, a copper layer and an aluminum layer, barrier layers such as a titanium nitride layer and a tantalum nitride layer or dielectric material layers such as a barium strontium titanate (BaSrTiOx) layer, a strontium bismuth tantalum oxide (SrBiTaOx) layer, a silicon oxyfluoride (SiOF) layer or a silicon dioxide layer.

Because the temperature inside the reaction chamber of a chemical vapor deposition station is very likely to affect final quality of the products, the deposition temperature inside the reaction chamber is normally set as soon as the system is built or during preventive maintenance. The principle method of setting the deposition temperature is through a thermocouple.

However, to set the deposition temperature, the reaction chamber must be opened up. Hence, environmental conditions inside the reaction chamber may be changed (a change in degree of vacuum). Consequently, before the reaction chamber is suitable for depositing thin film on a semi-finished wafer product, someone has to restart the station and wait for the passage of a moderately long idle period so that the environmental conditions inside the chamber such as particle distribution and depositing temperature are reconstituted.

The previous discussion indicates that using a thermocouple to determine the deposition temperature inside the chemical vapor deposition station demands a long waiting period before the station is productive again. Therefore, time needed to complete a preventive maintenance of the conventional chemical vapor deposition station is usually long.

Moreover, there is no way of determining the temperature inside the reaction chamber during a normal production flow using the thermocouple measurement method. In other words, any changes in the depositing temperature inside the reaction chamber will only be discovered after defects are found in the semi-finished or finished products or a temperature measurement is carried out in a routine maintenance of the station. By the time the temperature change is discovered through the defective semi-finished or finished products, numerous batches of products may have already been manufactured using the station. Hence, overall production yield is likely to drop.

### SUMMARY OF INVENTION

Accordingly, one object of the present invention is to provide a method of determining the temperature inside a reaction chamber such that the temperature inside the reaction chamber of a chemical vapor deposition station can be constantly monitored.

A second object of this invention is to provide a method of determining the deposition temperature inside a reaction chamber such that preventive maintenance of the deposition station can be reduced considerably.

A third object of this invention is to provide a method of determining the deposition temperature inside a reaction chamber such that production yield of the deposition station can be increased considerably.

To achieve these and other advantages and in accordance with the purpose of the invention, as embodied and broadly described herein, the invention provides a method of determining the deposition temperature inside the reaction chamber of a chemical vapor deposition station. The method includes placing a deposition substrate inside the reaction chamber, forming a layer of metal silicide over the deposition substrate, measuring the silicon/metal atomic ratio and finding the deposition temperature according to a pre-determined temperature versus silicon/metal atomic ratio relationship.

This invention also provides an alternative method of monitoring the deposition temperature inside the reaction chamber of a chemical vapor deposition station. A silicon/metal atom ratio versus deposition temperature relationship inside the reaction chamber is established in the station. The method includes placing a deposition substrate inside the reaction chamber, depositing a metal silicide layer over the deposition substrate, measuring the silicon/metal atomic ratio of the metal silicide layer and feeding the silicon/metal atomic ratio value back to the station so that a deposition temperature is found through the silicon/metal atomic ratio versus temperature relationship. After obtaining the deposition temperature, environmental factors of the station are adjusted to return the deposition temperature inside the reaction chamber to a desired value.

In this invention, the silicon/metal atomic ratio of a deposited film over a test plate is directly measured to obtain the true deposition temperature inside the reaction chamber. Since opening up the reaction chamber to get the temperature measurement is not required, there is no need to wait for the reconstitution of environmental conditions inside reaction chamber back to normal. Hence, considerable time in preventive maintenance is saved.

In addition, the method of determining deposition temperature can be applied even in a production flow. Deposition temperature can be found by measuring the atomic ratio of the deposited film over the test plate at any time such as after producing a definite quantity of semi-finished product, after a specified period or as soon as defects are found in the semi-finished products. In other words, the deposition station can be monitored at any time. Hence, yield of the reaction chamber is increased.

It is to be understood that both the foregoing general description and the following detailed description are exemplary, and are intended to provide further explanation of the invention as claimed.

### Brief Description of Drawings

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a flow chart showing the steps for determining the deposition temperature inside the chamber of a chemical vapor deposition station according to this invention; and

FIG. 2 is a graph showing a relationship between the silicon/tungsten atomic ratio and the deposition temperature inside the reaction chamber of a chemical vapor deposition station.

### Detailed Description

Reference will now be made in detail to the present preferred embodiments of the invention, examples of which are illustrated in the accompanying drawings. Wherever possible, the same reference numbers are used in the drawings and the description to refer to the same or like parts.

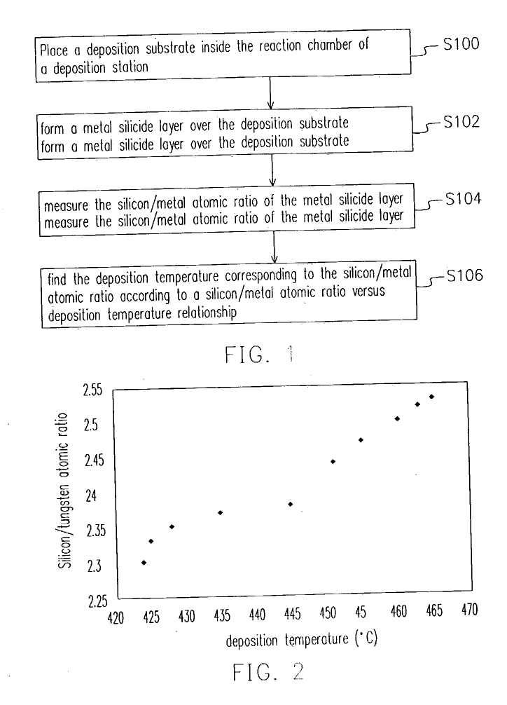

FIG. 1 is a flow chart showing the steps for determining the deposition temperature inside the chamber of a chemical vapor deposition station according to this invention. In step S100, a deposition substrate is placed inside the reaction chamber. The reaction chamber is the reaction chamber inside a chemical vapor deposition station and the deposition substrate is a test plate, for example.

In step S102, a metal silicide layer is deposited over the deposition substrate. The metal silicide layer is, for example, a tungsten silicide, titanium silicide, tantalum silicide, molybdenum silicide or a nickel silicide layer. For example, to form a tungsten silicide film over a test plate, gaseous tungsten hexafluoride and dichlorosilane (SiH₂Cl₂) are mixed together so that a layer of tungsten silicide is deposited over the test plate. The tungsten hexafluoride is used as a gaseous source of tungsten and the dichlorosilane or silane (SiH4) is used as a gaseous source of silicon.

In step S104, an X-ray screen analysis method is used to measure the silicon/metal atomic ratio of the metal silicide film on the test plate, for example. The method includes shining a beam of X-ray onto the metal silicide film and captures a reflected beam from the metal silicide film. Thereafter, the reflected beam is analyzed to obtain the silicon/metal atomic ratio.

In step S106, the silicon/metal atomic ratio is substituted into a formerly determined silicon/metal atomic ratio versus deposition temperature relationship to find the deposition temperature inside the reaction chamber of the chemical vapor deposition station. The aforementioned silicon/metal atomic ratio versus deposition temperature relationship is a relationship between the deposition temperature and the silicon/metal atomic ratio found using, for example, Rutherford Backscattering Spectrometry (RBS) or an X-ray analysis method. The relationship between deposition temperature and silicon/tungsten atomic ratio is drawn out in FIG. 2 to serve as a means of finding depositing temperature from a given silicon/tungsten atomic ratio.

When the method according to this invention is applied to the preventive maintenance of a chemical vapor deposition station, the atomic ratio of the metal silicide film on a test plate may be directly inspected to infer the deposition temperature inside the reaction chamber. After adjusting environmental parameters according to the measured temperature so that the deposition temperature inside the reaction chamber returns to a desired value, production may proceed immediately because there is no opening of the reaction chamber. Hence, unlike the convention method, there is no need to wait for the reconstitution of the state inside the reaction chamber after each preventive maintenance operation. Ultimately, preventive maintenance period is shortened and productivity is increased.

When the method according to this invention is applied to the actual production flow, the test plate may be inserted into the reaction chamber after the production a definite quantity of semi-finished products, or after a specified period or as soon as defects are found in the products. The aforementioned method of measuring the atomic ratio of the metal silicide film over the test plate can be used to find the deposition temperature inside the reaction chamber. By comparing the deposition temperature with the desired value, any difference between the two can be found so that some parameters may be set to close the temperature gap. In so doing, probability of producing defective products is greatly reduced.

In addition, the method according to this invention may be directly implemented by setting up a silicon/metal atomic ratio versus deposition temperature relationship inside a chemical vapor deposition station. As soon as the silicon/metal atomic ratio of a metal silicide film is measured, the precise deposition temperature is immediately obtained. Hence, any discrepancy between the deposition temperature and the desire temperature can be immediately rectified.

In summary, the silicon/metal atomic ratio of a deposited film over a test plate is directly measured to obtain the true deposition temperature inside the reaction chamber. Since opening up the reaction chamber to get the temperature measurement is not required, there is no need to wait for the reconstitution of environmental conditions inside reaction chamber back to normal. Hence, considerable time in preventive maintenance is saved.

In addition, the method of determining deposition temperature can be applied even in a production flow. Deposition temperature can be found by measuring the atomic ratio of the deposited film over the test plate at any time such as after producing a definite quantity of semi-finished product, after a specified period or as soon as defects are found in the semi-finished products. In other words, the deposition station can be monitored at any time. Hence, yield of the reaction chamber is increased.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A method of determining the deposition temperature inside the reaction chamber of a chemical vapor deposition station, comprising the steps of:
placing a deposition substrate inside the reaction chamber;
forming a metal silicide film over the deposition substrate;
measuring the silicon/metal atomic ratio of the metal silicide film; and
finding a deposition temperature corresponding to the silicon/metal atomic ratio through a pre-determined functional relationship between the silicon/metal atomic ratio and the deposition temperature.

2. The method of claim 1, wherein the silicon/metal atomic ratio of the deposited metal silicide film over the deposition substrate is measured using an X-ray analysis method.

3. The method of claim 1, wherein material constituting the metal silicide film includes tungsten silicide.

4. The method of claim 1, wherein material constituting metal silicide film is selected from a group consisting of titanium silicide, tantalum silicide, molybdenum silicide, cobalt silicide and nickel silicide.

5. The method of claim 1, wherein the functional relationship between the silicon/metal atomic ratio and the deposition temperature includes a functional formula relating the silicon/metal atomic ratio and the deposition temperature.

6. The method of claim 1, wherein the deposition substrate includes a test plate.

7. A method of monitoring the deposition temperature inside the reaction chamber of a chemical vapor deposition station, wherein the chemical vapor deposition station has already established a silicon/metal atomic ratio versus deposition temperature relationship, the method comprising the steps of:
placing a deposition substrate inside the reaction chamber of the station;
forming a metal silicide film over the deposition substrate;
measuring the silicon/metal atomic ratio of the metal silicide film; and
feeding the value of the silicon/metal atomic ratio into station to find the deposition temperature through the built-in the silicon/metal atomic ratio versus deposition temperature relationship.

8. The method of claim 7, wherein the deposition temperature inside the reaction chamber is adjusted to match a preset deposition temperature if the deposition temperature found by measuring the silicon/metal atomic ratio differs from the preset deposition temperature.

9. The method of claim 7, wherein the silicon/metal atomic ratio of the deposited metal silicide film over the deposition substrate is measured using an X-ray analysis method.

10. The method of claim 7, wherein material constituting the metal silicide film includes tungsten silicide.

11. The method of claim 7, wherein material constituting metal silicide film is selected from a group consisting of titanium silicide, tantalum silicide, molybdenum silicide, cobalt silicide and nickel silicide.

12. The method of claim 7, wherein the functional relationship between the silicon/metal atomic ratio and the deposition temperature includes a functional formula relating the silicon/metal atomic ratio and the deposition temperature.

13. The method of claim 7, wherein the deposition substrate includes a test plate.
